(19) United States
(12) Patent Application Publication
(10) Pub. No.: US 2025/0253219 A1
(43) Pub. Date: Aug. 7, 2025

(54) PRESS-FIT TERMINAL AND SEMICONDUCTOR DEVICE

(71) Applicant: FUJI ELECTRIC CO., LTD., Kawasaki-shi (JP)

(72) Inventor: Tomomi NONAKA, Kawasaki-shi (JP)

(73) Assignee: FUJI ELECTRIC CO., LTD., Kawasaki-shi (JP)

(21) Appl. No.: 19/007,258

(22) Filed: Dec. 31, 2024

(30) Foreign Application Priority Data
Feb. 1, 2024 (JP) 2024-013910

(51) Int. Cl. H01L 23/498

(52) U.S. Cl. CPC H01L 23/49811; H01L 23/49838

(57) ABSTRACT

A press-fit terminal includes a base portion and an insertion portion connected to the base portion and extending away from the base portion. The insertion portion is elastically deformable and configured to be press-fitted into the insertion hole in an insertion direction. The insertion portion has a cross section on a plane orthogonal to the insertion direction. The cross section of the insertion portion has four corner portions positioned at four corners of a rectangular respectively, and each are configured to be in contact with an inner surface of the insertion hole. The four corner portions of the cross section include at least one peripheral edge cut surface shape portion having a linear portion.

### CROSS-REFERENCE TO RELATED APPLICATION

This application is based upon and claims the benefit of priority to Japanese Patent Application No. 2024-013910, filed on Feb. 1, 2024, the entire contents of which are incorporated herein by reference.

### BACKGROUND OF THE INVENTION

### 1. Technical Field

The present invention relates to a press-fit terminal and a semiconductor device including the press-fit terminal.

### 2. Description of the Related Art

In the related art, a semiconductor device includes a circuit substrate on which a semiconductor element such as an insulated gate bipolar transistor (IGBT) is mounted, and is used for an inverter device or the like. In such a semiconductor device, a press-fit terminal that is press-fitted into an insertion hole such as a through hole of a substrate and is elastically deformed may be used (refer to, for example, JP 2017-126786 A, JP 2016-219778 A, and JP 2015-141857 A).

### SUMMARY OF THE INVENTION

If a peripheral edge of a cross section orthogonal to a press-fitting direction is angular, the press-fit terminal comes into contact with an inner peripheral wall of an insertion hole in a form close to point contact or does not fit in an opening portion of the insertion hole at the time of press-fitting. As a result, plating of the terminal and the insertion hole is scraped, an insertion load at the time of press-fitting or an extraction load at the time of extraction of is increased, or the terminal and the insertion hole cannot be press-fitted. On the other hand, when each of the four corners has a round surface (R surface) shape, the extraction load becomes small.

An object of the present invention is to provide a press-fit terminal and a semiconductor device capable of satisfying required performance or improving the ability to assemble

In one aspect, the press-fit terminal includes an elastically deformed portion press-fitted into an insertion hole, the elastically deformed portion has four corner regions in contact with the insertion hole at a peripheral edge of the cross section orthogonal to a press-fitting direction, and at least one of the corner regions is a peripheral edge cut surface shape portion.

In another aspect, the press-fit terminal includes an elastically deformed portion press-fitted into the insertion hole, and the elastically deformed portion includes an arc-shaped portion having a center side of the insertion hole as a center of curvature at both ends in a deformation direction of the elastically deformed portion in the cross section orthogonal to the press-fitting direction.

In a still another aspect, the press-fit terminal includes an elastically deformed portion press-fitted into the insertion hole, the elastically deformed portion is a pair of branch pieces that are bifurcated in a press-fitting direction, are separated from each other, and are curved such that tips thereof approach each other, and the pair of branch pieces have a tip chamfered shape portion at both ends in a deformation direction of the elastically deformed portion at the tips.

In a still another aspect, a semiconductor device includes any one of the press-fit terminals described above and a substrate provided with the insertion hole.

According to the above aspect, required performance can be satisfied or ability to assemble can be enhanced.

### BRIEF DESCRIPTION OF THE DRAWINGS

FIG. 1 is a cross-sectional view illustrating a semiconductor device in one embodiment;

FIG. 2 is a front view illustrating a press-fit terminal according to one embodiment;

FIG. 3A is a front view (part 1) for explaining insertion of a substrate (press-fitting of the press-fit terminal) in one embodiment;

FIG. 3B is a front view (part 2) for explaining insertion of a substrate (press-fitting of the press-fit terminal) in one embodiment;

FIG. 3C is a front view (part 3) for explaining insertion of a substrate (press-fitting of the press-fit terminal) in one embodiment;

FIG. 4A is a plan view illustrating an angular shape of an elastically deformed portion in Comparative Example 1;

FIG. 4B is a plan view illustrating an angle C shape of the elastically deformed portion in one embodiment;

FIG. 4C is a plan view illustrating an angle CR shape of the elastically deformed portion in one embodiment;

FIG. 4D is a plan view illustrating an angle R shape of the elastically deformed portion in Comparative Example 2;

FIG. 4E is a plan view illustrating an arc shape of the elastically deformed portion in one embodiment;

FIG. 4F is a plan view illustrating a zigzag angle CR shape of the elastically deformed portion in one embodiment;

FIG. 5 is an explanatory diagram illustrating a standard example of a plating residual thickness of a through hole in one embodiment;

FIG. 6 is an explanatory diagram illustrating a standard example of a plating scrape length of the press-fit terminal in one embodiment;

FIG. 7 is an explanatory diagram illustrating a standard example of an insertion load of the press-fit terminal in one embodiment;

FIG. 8 is an explanatory diagram illustrating a standard example of an extraction load of the press-fit terminal in one embodiment;

FIG. 9 is a plan view and a front view for explaining interference between a first branch piece of the press-fit terminal and the through hole at the time of eccentricity in one embodiment; and

FIG. 10 is a plan view and a front view for explaining a configuration for avoiding interference between the first branch piece of the press-fit terminal and the through hole at the time of eccentricity in one embodiment.

### DETAILED DESCRIPTION

Hereinafter, a press-fit terminal and a semiconductor device according to one embodiment of the present invention will be described with reference to the drawings. Note that the present invention is not limited to the embodiment described below, and thus appropriate modifications can be made without departing from the gist thereof.

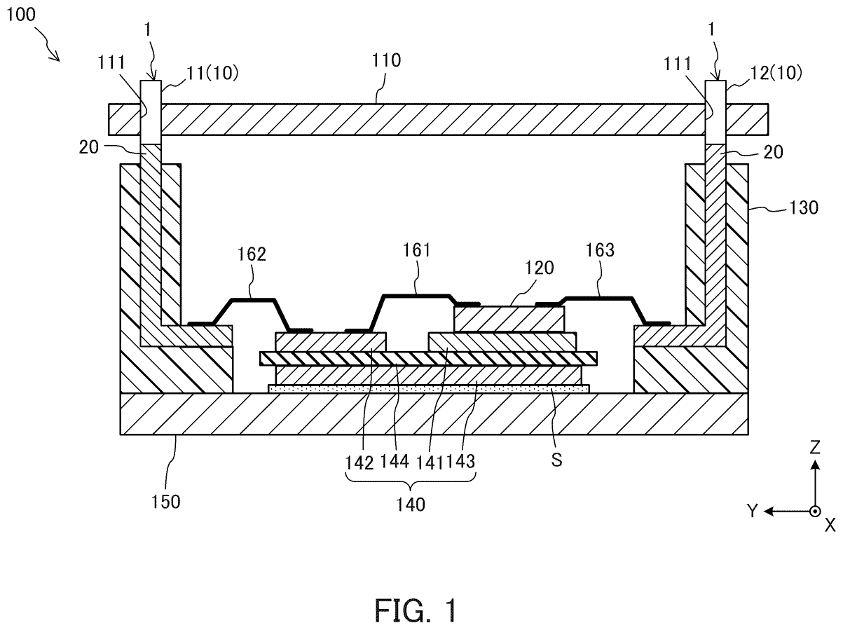

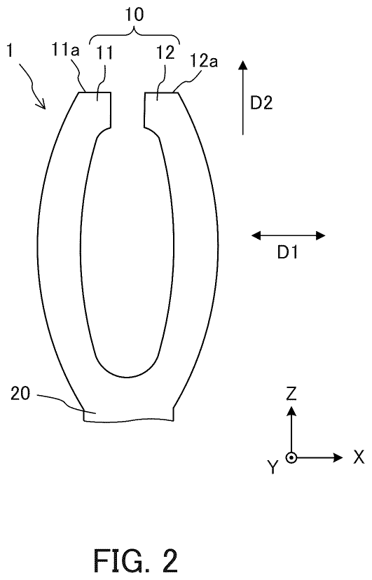

FIG. 1 is a cross-sectional view illustrating a semiconductor device 100, and FIG. 2 is a front view illustrating a press-fit terminal 1.

In an X direction, a Y direction, and a Z direction illustrated in FIGS. 1 and 2 and FIGS. 3A to 3C, FIGS. 4A to 4F, and FIGS. 9 and 10 to be described later, a press-fitting direction D2 of the press-fit terminal 1 is defined as the positive side in the Z direction, and a deformation direction D1 of the elastically deformed portion 10 of the press-fit terminal 1 in the X direction and the Y direction orthogonal to the Z direction and orthogonal to each other is defined as the X direction. In some cases, the X direction may be referred to as a left-right direction, the Y direction may be referred to as a front-back direction, and the Z direction may be referred to as a vertical direction. Such directional terms are used for convenience of description, and the correspondence relationship in the XYZ directions changes depending on the postures of the press-fit terminal 1 and the semiconductor device 100.

The semiconductor device 100 illustrated in FIG. 1 includes a plurality of press-fit terminals 1, a substrate 110, a semiconductor element 120, a case 130, a multi-layer substrate 140, a metal base 150, and wirings 161 to 163.

As an example, the semiconductor device 100 is applied to a power conversion device such as an inverter device of an industrial or in-vehicle motor together with a cooler (not shown) disposed below the metal base 150. In the following description, detailed description of the same or similar configuration, function, operation, assembly method, and the like as those of known press-fit terminal 1 and semiconductor device 100 will be omitted. The press-fit terminal 1 can also be used for applications other than the semiconductor device 100.

As illustrated in FIG. 2, the press-fit terminal 1 includes an elastically deformed portion (insertion portion) 10 and a base portion 20. The press-fit terminal 1 is, for example, a metal material such as copper, a copper alloy, brass, or stainless steel plated with nickel (plated with Sn on the outermost layer).

The elastically deformed portion 10 includes a first branch piece 11 and a second branch piece 12. The first branch piece 11 and the second branch piece 12 are a pair of branch pieces that are branched from the base portion 20, and are curved in opposite directions (direction +X/direction −X, deformation direction D1) so that tips 11a, 12a thereof approach each other. Specifically, the first branch piece 11 and the second branch piece 12 are bifurcated in the press-fitting direction (insertion direction) D2 into the through hole 111, are separated from each other in the deformation direction D1, and are curved such that the tips 11a and 12a thereof approach each other. For example, the first branch piece and the second branch piece have a plate shape in which the thickness direction is the Y direction. The elastically deformed portion 10 can also be referred to as a press-fit portion or the like, and when having the first branch piece 11 and the second branch piece 12, can also be referred to as a U-shaped portion, a crab-claw-shaped portion, a crab-scissor-shaped portion, or the like. The elastically deformed portion 10 may not have a branch piece, and may have another shape such as a shape in which the tip 11a of the first branch piece 11 and the tip 12a of the second branch piece 12 are integrated and the center is opened, for example.

The base portion 20 is provided integrally with the elastically deformed portion 10 on the negative side in the Z direction of the elastically deformed portion 10. In the example of FIG. 1, the base portion 20 has an L-shaped plate shape. The shape of the base portion 20 is not particularly limited similarly to the shape of the elastically deformed portion 10.

The substrate 110 illustrated in FIG. 1 is disposed above the case 130. The substrate 110 is provided with a through hole 111 for electrical connection as an example of an insertion hole into which the elastically deformed portion 10 is press-fitted. The substrate 110 is an example of a member electrically connected to the press-fit terminal 1.

The semiconductor element 120 is joined onto a first conductor plate 141 by a conductive joining material (not shown) such as solder. The semiconductor element 120 is formed of, for example, a reverse conducting (RC)-insulated gate bipolar transistor (IGBT) element obtained by integrating an IGBT element that is a switching element and a diode element such as a free wheeling diode (FWD) element or the like connected to the IGBT element and the switching element in an inverse parallel manner. The switching element and the diode element in the semiconductor element 120 are not limited to be formed on a Si substrate, and may be formed on a semiconductor substrate using a wide band gap semiconductor such as silicon carbide (SiC) or gallium nitride (GaN), for example. This type of semiconductor element 120 is provided with electrodes (not shown) on a lower surface and an upper surface. The semiconductor element 120 is electrically connected to the wirings 161 and 163 by a conductive joining material at an electrode provided on the upper surface. In addition, the semiconductor element 120 is connected to one press-fit terminal 1 in FIG. 1 via the wiring 163, and is connected to the other press-fit terminal 1 in FIG. 1 via the wirings 161 and 162 and the second conductor plate 142. The press-fit terminal 1 can be used as a main terminal such as an output terminal and an input terminal (P terminal and N terminal), or an optional terminal such as a control terminal.

The case 130 has, for example, a quadrangular cylindrical shape with the Z direction as a central axis, and houses the semiconductor element 120 and the like. The case 130 is formed, for example, using an insulating resin material such as poly phenylene sulfide (PPS) or poly amide (PA). The case 130 is bonded to the upper surface of the metal base 150.

The case 130 is integrally molded with the plurality of press-fit terminals 1 in a state where both ends of the press-fit terminals 1 are exposed. The semiconductor element 120, the first conductor plate 141, the second conductor plate 142, and the like in the case 130 are sealed with a sealing material (not shown). The sealing material is an epoxy resin, silicone gel, or the like, for example. A cover is preferably provided above the sealing material over the entire XY plane of a hollow portion of the case 130.

The multi-layer substrate 140 includes the first conductor plate 141, the second conductor plate 142, a third conductor plate 143, and an insulating substrate 144. The first conductor plate 141 and the second conductor plate 142 are provided on the upper surface of the insulating substrate 144, and the third conductor plate 143 is provided on the lower surface of the insulating substrate 144. The multi-layer substrate 140 is, for example, a direct copper bonding (DCB) substrate or an active metal brazing (AMB) substrate.

The first conductor plate 141 and the second conductor plate 142 are members that function as a wiring member in the inverter circuit and are formed of, for example, a metal plate, a metal foil, or the like of copper, aluminum, or the like. The first conductor plate 141 and the second conductor plate 142 may also be referred to as a conductor layer, a conductive layer, a conductor pattern, a wiring pattern, or the like.

The third conductor plate 143 is a member that functions as a heat conducting member for conducting heat generated in the inverter circuit to the metal base 150 and is formed of, for example, a metal plate, a metal foil, or the like of copper, aluminum, or the like. The third conductor plate 143 is bonded to the metal base 150 by a conductive joining material S such as solder. The third conductor plate 143 may be also referred to as a heat dissipation layer, a heat dissipation plate, a conductor pattern, a heat dissipation pattern, or the like.

The insulating substrate 144 may be, for example, a ceramic substrate formed of a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 144 may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like.

The metal base 150 is a rectangular plate-shaped member. The metal base 150 is a member that functions as a heat conducting member that conducts heat generated by the semiconductor element 120 to the cooler (not shown), and is formed of a metal plate such as a copper plate or an aluminum plate, for example. The metal base 150 and the cooler are connected via a thermal conductive material such as a thermal grease or a thermal compound. The metal base 150 may have a function of a cooler.

The wirings 161 to 163 are, for example, lead frames or wires. The wiring 161 connects the semiconductor element 120 and the second conductor plate 142. The wiring 162 connects the second conductor plate 142 and the base portion 20 of the press-fit terminal 1 on the positive side in the Y direction. The wiring 163 connects the semiconductor element 120 and the base portion 20 of the press-fit terminal 1 on the negative side in the Y direction.

In the above description, the case where the press-fit terminal 1 is disposed in the semiconductor device 100 has been described as an example, but the application of the press-fit terminal 1 is not limited to the semiconductor device 100, and may be used in any device. In addition, a circuit of the semiconductor device 100 described above includes a switching element, a diode element, and the like inside the semiconductor element 120, and the semiconductor device 100 may constitute any circuit such as a single-phase voltage half-bridge inverter circuit, a single-phase full-bridge inverter circuit, or a three-phase AC inverter circuit. In addition, the above description of the semiconductor device 100 is merely an example, and the semiconductor device 100 may include a substrate 110 provided with a through hole 111 (an example of an insertion hole) into which the elastically deformed portion 10 of the press-fit terminal 1 is press-fitted.

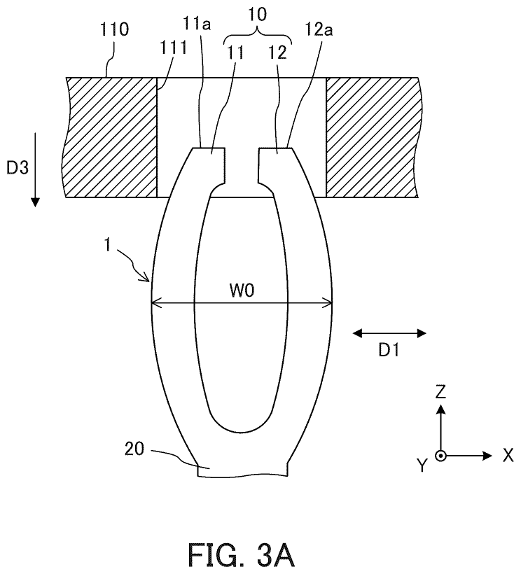

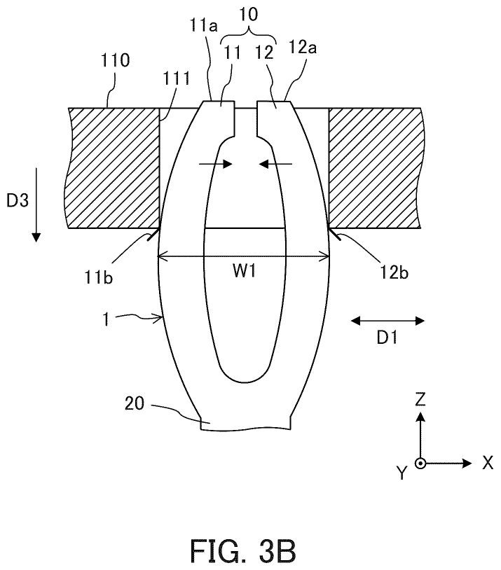

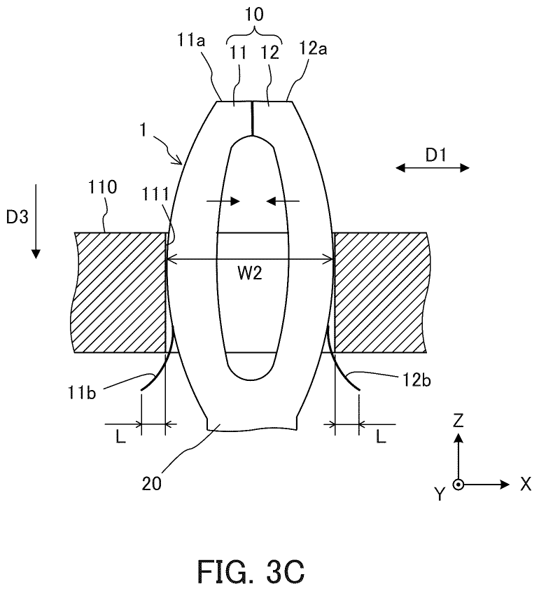

Next, the insertion of the substrate 110 (press-fitting of the press-fit terminal 1) will be described with reference to front views of FIGS. 3A to 3C.

First, as illustrated in FIG. 3A, for example, a manufacturing device of the semiconductor device 100 positions the plurality of through holes 111 of the substrate 110 at the positions of the plurality of press-fit terminals 1, and then moves the substrate 110 to the negative side in the Z direction (substrate insertion direction D3). As a result, the elastically deformed portion 10 exposed upward from the case 130 illustrated in FIG. 1 enters the cylindrical through hole 111. Before the elastically deformed portion 10 is elastically deformed, the maximum width WO of the elastically deformed portion 10 in the deformation direction D1 (X direction) is larger than an inner diameter of the through hole 111. Instead of the substrate 110 moving to the negative side in the Z direction as described above, the press-fit terminal 1 (elastically deformed portion 10) may be press-fitted by moving the press-fit terminal 1 (case 130) to the positive side in the Z direction.

Next, as illustrated in FIG. 3B, when the substrate 110 is pressed in the substrate insertion direction D3, the elastically deformed portion 10 is elastically deformed so as to be compressed in the deformation direction D1 while both ends of the first branch piece 11 and the second branch piece 12 in the deformation direction D1 come into with the inner peripheral wall of the through hole 111. When the elastically deformed portion 10 is deformed, the tips 11a and 12a of the first branch piece 11 and the second branch piece 12 are elastically deformed so as to approach each other. Therefore, immediately after the start of the elastic deformation, the maximum width W1 of the elastically deformed portion 10 becomes shorter than the maximum width W0 before the elastic deformation. When both ends of the elastically deformed portion 10 in the deformation direction D1 come into contact with the inner peripheral wall of the through hole 111, excessive force is generated at the contact point in the first branch piece 11 and the second branch piece 12, and plating scrapes 11b and 12b are generated by being pierced (bitten). Although not shown, the through hole 111 causes scraping or deformation of a plating layer.

As illustrated in FIG. 3C, when the insertion of the substrate 110 in the substrate insertion direction D3 is completed, the elastically deformed portion 10 is further compressed in the deformation direction D1, and the first branch piece 11 and the second branch piece 12 come into contact with each other. In this state, since the elastic force of the elastically deformed portion 10 acts strongly, so that the elastically deformed portion 10 is unlikely to come out even if it is extracted in the direction opposite to the press-fitting direction D2. Since the maximum width W2 of the elastically deformed portion 10 after the press-fitting coincides with the inner diameter of the through hole 111, the maximum width W2 is shorter than the maximum width W1 immediately after the start of the elastic deformation. Further, the plating scrapes 11b and 12b of the first branch piece 11 and the second branch piece 12 increase. A length protruding from the through hole 111 in the deformation direction D1 of the plating scrapes 11b and 12b is a scrape length L. When the scrape length L increases, a problem such as a wiring short circuit may occur. In FIG. 3C, since the diameter of the through hole 111 is a standard size with respect to the press-fit terminal 1, the first branch piece 11 and the second branch piece 12 come into surface contact with each other in the planar portion (YZ plane). However, for example, when the through hole 111 has a minimum diameter, the first branch piece and the second branch piece can come into contact with each other only on the base side (end portion on the negative side in the Z direction) of the planar portion, and when the through hole 111 has a maximum diameter, the first branch piece and the second branch piece can come into contact with each other only on the tip side (end portion on the positive side in the Z direction) of the planar portion.

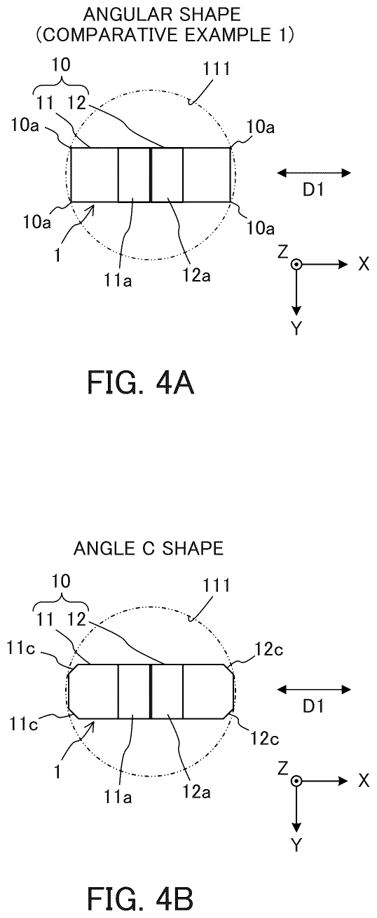

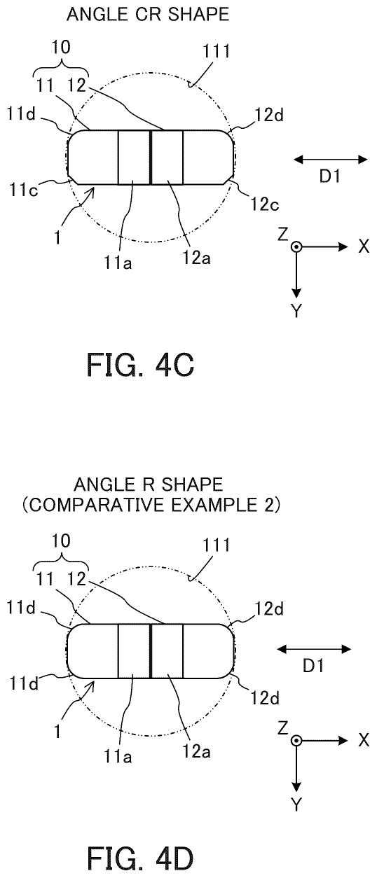

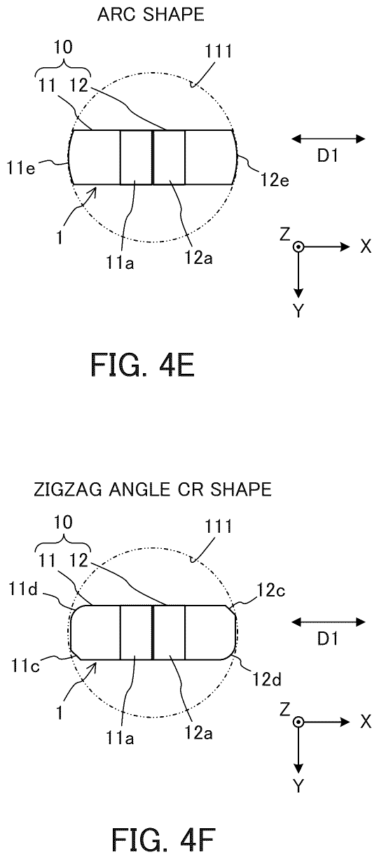

As illustrated in FIG. 4A (Comparative Example 1 having an angular shape), when the four corner regions 10a positioned at the peripheral edge of the cross section on a X-Y plane, which is orthogonal to the press-fitting direction D2 (positive side in the Z direction), of the elastically deformed portion 10 and in contact with the through hole 111 are angularly set at a right angle, the elastically deformed portion 10 is press-fitted into the through hole 111 while the elastically deformed portion 10 and the through hole 111 come into contact with each other in a state close to the point contact. Therefore, the scrape length L of the plating scrapes 11b and 12b is increased. Here, the four corner regions 10a positioned at the peripheral edge of the cross-section orthogonal to the press-fitting direction D2 of the elastically deformed portion 10 and in contact with the through hole 111 are four corner regions 10a that are places in contact with the inner peripheral wall of the through hole 111, that is, an end portion on the positive side in the X direction (deformation direction D1) and on the positive side in the Y direction (direction orthogonal to the X direction in the cross section), an end portion on the positive side in the X direction and on the negative side in the Y direction, an end portion on the negative side in the X direction and on the positive side in the Y direction, and an end portion on the negative side in the X direction and on the negative side in the Y direction. In the example of FIG. 4A, since the elastically deformed portion 10 includes the first branch piece 11 and the second branch piece 12, two of the four corner regions 10a are formed in the first branch piece 11 and two in the second branch piece 12. Note that the four corner regions 10a can also be referred to as regions that connect a side in the X direction (deformation direction D1 of the elastically deformed portion 10 (or the press-fit terminal 1)) and a side in the Y direction (direction orthogonal to the X direction) of the press-fit terminal 1 in a cross-sectional view orthogonal to the press-fitting direction D2. In other words, the four corner regions 10a can be said to be regions of four corners of a rectangular region (or substantially rectangular region) formed by the first branch piece 11, the second branch piece 12, and a region sandwiched therebetween in a cross-sectional view orthogonal to the press-fitting direction D2.

As illustrated in FIG. 4B (angle C shape), it is preferable that the peripheral edge cut surface shape portions 11c and 12c are provided in the four corner regions 10a (refer to FIG. 4A) of the peripheral edge of the elastically deformed portion 10 (the first branch piece 11 and the second branch piece 12). The peripheral edge cut surface shape portions each have a liner portion. The peripheral edge cut surface shape portions 11c and 12c are provided over the entire elastically deformed portion 10 in the press-fitting direction D2, for example. However, the peripheral edge cut surface shape portions 11c and 12c may be provided in at least a part of the elastically deformed portion 10 that can come into contact with the through hole 111 (a portion having a larger diameter than the through hole 111 before press-fitting). Note that the elastically deformed portion 10 having the peripheral edge cut surface shape portions 11c and 12c may be formed by chamfering as a post-process, but may be formed by any molding method, pressing method, or the like.

As illustrated in FIG. 4C (angle CR shape), among the four corner regions 10a (refer to FIG. 4A) of the peripheral edge of the elastically deformed portion 10 (the first branch piece 11 and the second branch piece 12), the peripheral edge cut surface shape portions 11c and 12c may be provided in the corner region 10a on the positive side in the Y direction, and peripheral edge round surface shape portions 11d and 12d may be provided in the corner region 10a on the negative side in the Y direction. The peripheral edge round surface shape portions 11d and 12d each have a rounded portion that may correspond to a segment of a circumference of the insertion hole 111. The peripheral edge cut surface shape portions 11c and 12c and the peripheral edge round surface shape portions 11d and 12d are also provided over the entire elastically deformed portion 10 in the press-fitting direction D2, for example. However, the peripheral edge cut surface shape portions may be provided in at least a part of the elastically deformed portion 10 that can come into contact with the through hole 111 (a portion having a larger diameter than the through hole 111 before press-fitting).

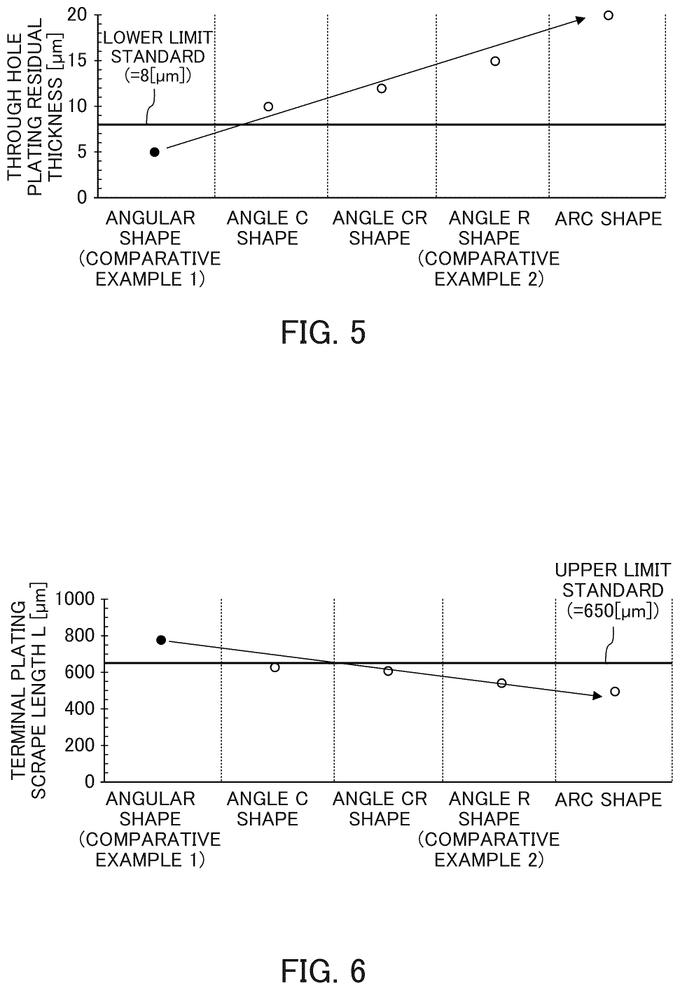

As illustrated in FIG. 4D (Comparative Example 2 of the angle R shape), in a case where the peripheral edge round surface shape portions 11d and 12d are provided in all the four corner regions 10a (refer to FIG. 4A) of the peripheral edge of the elastically deformed portion 10 (the first branch piece 11 and the second branch piece 12), although the plating residual thickness [μm] of the through hole 111 illustrated in FIG. 5 is not extremely thick, the extraction load [N] when the press-fit terminal 1 illustrated in FIG. 8 is extracted from the substrate 110 is a value close to 40 [N] of the lower limit standard.

As illustrated in FIG. 4E (arc shape), the arc-shaped portions 11e and 12e with the center side of the through hole 111 as the center of curvature may be provided at both ends of the elastically deformed portion 10 (the first branch piece 11 and the second branch piece 12) in the deformation direction D1. The arc-shaped portions 11e and 12e preferably have a radius of curvature equal to or close to a radius of the through hole 111. That is, an acc of each of the arc-shaped portions 11e and 12e is formed to correspond to a segment of a circumference of the insertion hole 111. The arc-shaped portions 11e and 12e are also provided, for example, over the entire elastically deformed portion 10 in the press-fitting direction D2, but may be provided in at least a part of the elastically deformed portion 10 that can come into contact with the through hole 111. The arc-shaped portions 11e and 12e can also be referred to as surface holes (inner peripheral wall of the through hole 111) fit shapes.

Note that the centers of curvature of the arc-shaped portions 11e and 12e are in a state where the press-fit terminal 1 is inserted into the through hole 111, and when the maximum width W2 of the elastically deformed portion 10 coincides with the inner diameter of the through hole 111, the centers of curvature are near the center of the through hole 111. Before the press-fit terminal 1 is inserted into the through hole 111, when the elastically deformed portion 10 has the maximum width W1, the centers of curvature of the arc-shaped portions 11e and 12e exist at positions separated from each other by the distance between the maximum width W1 and the maximum width W2.

When the radius of curvature of the arc-shaped portions 11e and 12e is smaller than the radius of the through hole 111, the through hole 111 is in contact with one central portion of each of the arc-shaped portions 11e and 12e. When the radius of curvature of the arc-shaped portions 11e and 12e is larger than the radius of the through hole 111, the through hole 111 is in contact with two end portions of the arc-shaped portions 11e and 12e. When the ratio of the radius of curvature of the arc-shaped portions 11e and 12e to the radius of the through hole 111 is higher than 100% in the relationship of the contact area with respect to the through hole 111, the extraction load increases, the insertion load increases, the terminal plating scrape length increases, and the through hole plating residual film decreases. Similarly, when it is less than 100% in relation of the contact area with the through hole 111, the extraction load decreases, the insertion load decreases, the terminal plating scrape length decreases, and the through hole plating residual film increases.

The radius of curvature of the arc-shaped portions 11e and 12e is desirably 80% to 150% of the radius of the through hole 111. This is a range in which the thickness of the press-fit terminal 1 in the Y direction is 50% of the thickness of the through hole 111, and a gap is 5% or less when the press-fit terminal 1 is inserted into the through hole 111. As described above, in a case where the radius of curvature of the arc-shaped portions 11e and 12e is smaller than the radius of the through hole 111, the through hole 111 is in contact with one central portion of each of the arc-shaped portions 11e and 12e, and thus, this gap serves as both end portions of each of the arc-shaped portions 11e and 12e. In a case where the radius of curvature of the arc-shaped portions 11e and 12e is larger than the radius of the through hole 111, the through hole 111 is in contact with two end portions of each of the arc-shaped portions 11e and 12e, and thus, this gap serves as the central portion of each of the arc-shaped portions 11e and 12e. When the relationship between the thickness of the press-fit terminal 1 and the diameter of the through hole 111 is different, the ratio of the radius of curvature of the arc-shaped portions 11e and 12e may be appropriately adjusted with respect to the radius of the through hole 111 so that the gap becomes 5% or less when the press-fit terminal 1 is inserted into the through hole 111.

As illustrated in FIG. 4F (zigzag angle CR shape), among the four corner regions 10a (refer to FIG. 4A) of the peripheral edge of the elastically deformed portion 10 (the first branch piece 11 and the second branch piece 12), the peripheral edge cut surface shape portion 11c may be provided in the corner region 10a on the positive side in the Y direction of the elastically deformed portion 10 of the first branch piece 11, the peripheral edge round surface shape portion 11d may be provided in the corner region 10a on the negative side in the Y direction, the peripheral edge round surface shape portion 12d may be provided in the corner region 10a on the positive side in the Y direction of the second branch piece 12, and the peripheral edge cut surface shape portion 12c may be provided in the corner region 10a on the negative side in the Y direction. In this case, it can be said that two peripheral edge cut surface shape portions 11c and 12c are provided so as to face each other in the diagonal direction of one of the four corner regions 10a, and two peripheral edge round surface shape portions 11d and 12d are provided so as to face each other in the other diagonal direction of the four corner regions 10a.

Note that at least one of the four corner regions 10a of the peripheral edge of the elastically deformed portion 10 having the peripheral edge cut surface shape portions 11c and 12c may be angularly set at a right angle, for example. However, desirably, all the corner regions 10a may have a non-angular shape (shape chamfered by peripheral edge cut surface shape portions 11c and 12c and peripheral edge round surface shape portions 11d and 12d).

As illustrated in FIG. 5, the plating residual thickness [μm] of the through hole 111 after press-fitting of the press-fit terminal 1 is measured by, for example, a cross-sectional observation, and the lower limit standard is generally set to 8 [μm]. The plating residual thickness [μm] falls below the lower limit standard at about 5 [μm] (indicated by black circles) in the angular shape (Comparative Example 1) illustrated in FIG. 4A, whereas it exceeds the lower limit standard at the angle C shape (about 10 [μm]) illustrated in FIG. 4B, the angle CR shape (about 12 [μm]) illustrated in FIG. 4C, the angle R shape (Comparative Example 2) (about 15 [μm]) illustrated in FIG. 4D, and the arc shape (about 20 [μm]) illustrated in FIG. 4E. In addition, the arc-shaped elastically deformed portion 10 illustrated in FIG. 4E has an extremely large plating residual thickness [μm] of about 20 [μm], which is particularly effective from the viewpoint of increasing the plating residual thickness. Although the same applies to FIGS. 6 to 8 described later, the description of the elastically deformed portion 10 having the zigzag angle CR shape illustrated in FIG. 4F is omitted.

As illustrated in FIG. 6, the scrape length L (refer to FIG. 3C) of the plating scrapes 11b and 12b of the press-fit terminal 1 (elastically deformed portion 10) after press-fitting is, for example, the longest length of plating scrapes 11b and 12b, and the upper limit standard is set at 650 [μm]. The scrape length L [μm] exceeds the upper limit standard at about 780 [μm] (indicated by black circles) in the angular shape (Comparative Example 1) illustrated in FIG. 4A, whereas it falls below the upper limit standard at the angle C shape (about 630 [μm]) illustrated in FIG. 4B, the angle CR shape (about 600 [μm]) illustrated in FIG. 4C, the angle R shape (Comparative Example 2) (about 550 [μm]) illustrated in FIG. 4D, and the arc shape (about 500 [μm]) illustrated in FIG. 4E. In addition, since the arc-shaped elastically deformed portion 10 illustrated in FIG. 4E has the shortest scrape length L [μm] of about 550 [μm], it can be said to be particularly effective from the viewpoint of shortening the scrape length L.

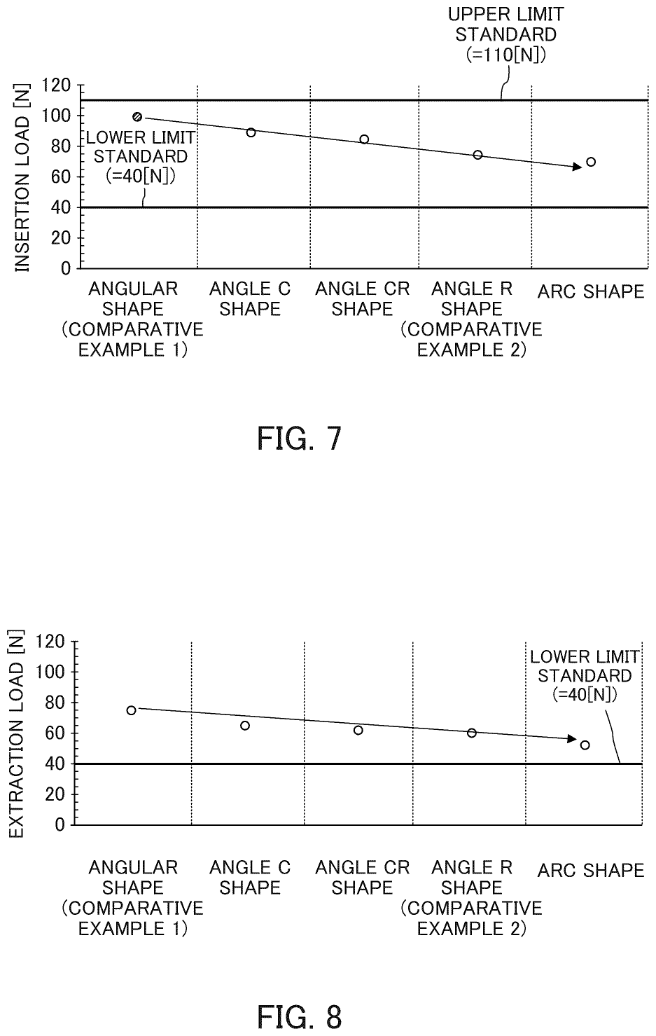

As illustrated in FIG. 7, the insertion load [N] required at the time of insertion (at the time of press-fitting) of the press-fit terminal 1 (elastically deformed portion 10) into the through hole 111 is, for example, a load per one press-fit terminal 1, and the upper limit standard is set to 110 [N] and the lower limit standard is set to 40 [N]. It can be said that the insertion load [N] is close to the upper limit standard and has a small margin although the angular shape (Comparative Example 1) illustrated in FIG. 4A is about 100 [N] (illustrated by hatched circles) and falls between the upper limit standard and the lower limit standard. On the other hand, in the angle C shape (about 90 [N]) illustrated in FIG. 4B, the angle CR shape (about 85 [N]) illustrated in FIG. 4C, the angle R shape (Comparative Example 2) (about 75 [N]) illustrated in FIG. 4D, and the arc shape (about 70 [N]) illustrated in FIG. 4E, it can be said that the difference between the upper limit standard and the lower limit standard is relatively large. In particular, the arc-shaped elastically deformed portion 10 illustrated in FIG. 4E has a sufficient difference from the upper limit standard and the lower limit standard, and the insertion load [N] is as small as about 70 [N], which can be said to be effective also from the viewpoint of the insertion load.

As illustrated in FIG. 8, the extraction load [N] required at the time of extracting the press-fit terminal 1 (elastically deformed portion 10) from the through hole 111 is, for example, a load per one press-fit terminal 1, and the lower limit standard is defined as 40 [N]. The insertion load [N] exceeds the lower limit standard in all of the angular shape (Comparative Example 1) (about 75 [N]) illustrated in FIG. 4A, the angle C shape (about 65 [N]) illustrated in FIG. 4B, the angle CR shape (about 62 [N]) illustrated in FIG. 4C, the angle R shape (Comparative Example 2) (about 60 [N]) illustrated in FIG. 4D, and the arc shape (about 52 [N]) illustrated in FIG. 4E. Note that the arc-shaped elastically deformed portion 10 illustrated in FIG. 4E has the smallest insertion load [N] of about 52 [μm], and thus is inferior to other shapes from the viewpoint of increasing the insertion load [N].

Note that the standards of the lower limit and the upper limit of the plating residual thickness [μm] illustrated in FIG. 5, the scrape length L [μm] illustrated in FIG. 6, the insertion load [N] illustrated in FIG. 7, and the extraction load [N] illustrated in FIG. 8 described above vary depending on, for example, the material, shape, and dimensions (width in deformation direction D1, thickness in Y direction, and the like) of the press-fit terminal 1 and the material, inner diameter, and the like of the through hole 111, and thus are merely examples. However, in designing and manufacturing the press-fit terminal 1 and the through hole 111 so as to satisfy the standard values, it is found that it is effective to select the shape of the peripheral edge in contact with the through hole 111 in the cross-section orthogonal to the press-fitting direction D2 of the elastically deformed portion 10 according to the required performance.

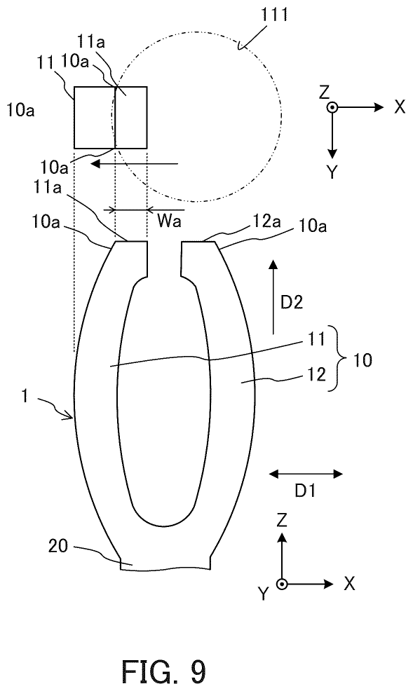

Meanwhile, as illustrated in FIG. 9, the press-fit terminal 1 may be eccentric with respect to the through hole 111 due to the influence of the assembly accuracy of the semiconductor device 100, the processing accuracy and tolerance of each part, and the like. Such eccentricity similarly occurs even when the press-fit terminal 1 is press-fitted after the positions of the plurality of through holes 111 of the substrate 110 are aligned with the positions of the plurality of press-fit terminals 1 using a manufacturing device. In the example of FIG. 9, the press-fit terminal 1 is eccentric to the negative side in the X direction with respect to the through hole 111. In this case, particularly when the widths (overall widths including width Wa of first branch piece 11, width of second branch piece 12, and width of gap between first branch piece 11 and second branch piece 12) of the tips 11a and 12a of the elastically deformed portion 10 (the first branch piece 11 and the second branch piece 12) in the deformation direction D1 become longer as approaching the inner diameter of the through hole 111 (when the design margin is small), the tip 11a (width Wa) of the first branch piece 11 comes into contact with the lower end (opening portion) of the through hole 111, and the press-fit terminal 1 may not be press-fitted.

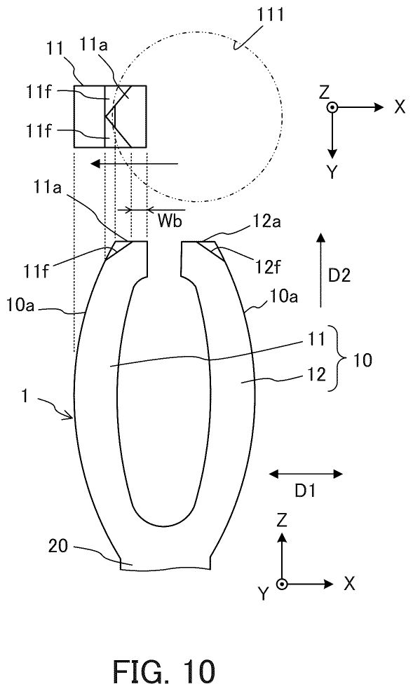

Therefore, as illustrated in FIG. 10, in the first branch piece 11 and the second branch piece 12, tip cut surface shape portions 11f and 12f are preferably provided at both ends in the deformation direction D1 of the elastically deformed portion 10 at the tips 11a and 12a. As a result, the areas (press-fitting start surfaces) of the tips 11a and 12a become narrower and closer to the center side in the Y direction, and the tips 11a and 12a of the first branch piece 11 and the second branch piece 12 are less likely to come into contact with the lower end (opening portion) of the through hole 111.

The tip cut surface shape portions 11f and 12f are preferably provided in at least one of the four corner regions 10a of the elastically deformed portion 10 described above at the tips 11a and 12a, that is, at least one of the four corner regions 10a (the corner region 10a on the positive side in the Y direction and the corner region 10a on the negative side in the Y direction) that is positioned at the peripheral edge of the cross section orthogonal to the press-fitting direction D2 of the elastically deformed portion 10 and is in contact with the through hole 111 (desirably, all of the four corner regions 10a) so as to form an inclined surface having a triangular shape in plan view. As a result, the width Wb of the tips 11a and 12a at both ends in the Y direction in the deformation direction D1 is sufficiently smaller than the width Wa (refer to FIG. 9) of the tips 11a and 12a of the portion where the tip cut surface shape portions 11f and 12f are not provided. The tip cut surface shape portions 11f and 12f are preferably provided at both ends in the Y direction of the tips 11a and 12a so that the width Wb in the deformation direction D1 decreases toward the positive side in the Z direction.

It is preferable that a total of four tip cut surface shape portions 11f and 12f are provided in the corner region 10a on the positive side in the Y direction and the corner region 10a on the negative side in the Y direction in the tips 11a and 12a of the first branch piece 11 and the second branch piece 12. However, a total of two tip cut surface shape portions 11f and 12f may be provided in each of the first branch piece 11 and the second branch piece 12 so as to extend over the entire Y direction. Here, the tip cut surface shape portions 11f and 12f are an example of a tip chamfered shape portion. The tip chamfered shape portion may be a tip round surface shape portion having a round shape in plan view or front view.

In addition, the peripheral edge cut surface shape portions 11c and 12c, the peripheral edge round surface shape portions 11d and 12d, the arc-shaped portions 11e and 12e, and the like are preferably provided below the tip cut surface shape portions 11f and 12f.

In the first aspect of the present embodiment described above, the press-fit terminal 1 includes the elastically deformed portion 10 press-fitted into the through hole 111 which is an example of the insertion hole. As illustrated in FIGS. 4B, 4C, and 4F, the elastically deformed portion 10 has four corner regions 10a in contact with the through hole 111 at the peripheral edge of the cross section orthogonal to the press-fitting direction D2, and at least one corner region 10a is the peripheral edge cut surface shape portions 11c and 12c at the peripheral edge. Further, in the second aspect, as illustrated in FIG. 4E, the elastically deformed portion 10 has arc-shaped portions 11e and 12e with the center side of the through hole 111 as the center of curvature at both ends in the deformation direction D1 of the elastically deformed portion 10 in the cross section orthogonal to the press-fitting direction D2. In addition, a semiconductor device 100 illustrated in FIG. 1 includes the press-fit terminal 1 according to the first or second aspect and a substrate 110 provided with a through hole 111 which is an example of an insertion hole. For example, the corner region 10a is a region that connects a side in the deformation direction D1 of the press-fit terminal 1 (elastically deformed portion 10) and a side in a direction orthogonal to the deformation direction D1 in a cross-sectional view orthogonal to the press-fitting direction D2.

Meanwhile, as in Comparative Example 1 illustrated in FIG. 4A, when the elastically deformed portion 10 is positioned at the peripheral edge of the cross section orthogonal to the press-fitting direction D2 and the four corner regions 10a in contact with the through hole 111 are angular, the elastically deformed portion comes into contact with the inner peripheral wall of the through hole 111 in a form close to point contact. On the other hand, in the first and second aspects of the present embodiment, since the peripheral edge cut surface shape portions 11c and 12c and the arc-shaped portions 11e and 12e are provided, stress concentration at the contact portion is alleviated, and the elastically deformed portion 10 comes into contact with the through hole 111 and is supported by repulsion in the entire wider contact portion. Therefore, it is possible to prevent the plating of the elastically deformed portion 10 and the through hole 111 from being scraped, and the insertion load at the time of press-fitting and the extraction load at the time of extraction of the elastically deformed portion 10 from becoming too large. In addition, as in Comparative Example 2 illustrated in FIG. 4D, in a case where only the peripheral edge round surface shape portions 11d and 12d are provided in the four corner regions 10a of the elastically deformed portion 10, for example, it cannot be said that it is particularly effective from the viewpoint of the plating residual thickness [μm] of the through hole 111 illustrated in FIG. 5, the plating scrape length L [μm] of the plating scrapes 11b and 12b of the press-fit terminal 1 (elastically deformed portion 10) illustrated in FIG. 6, and the insertion load [N] illustrated in FIG. 7, and by selectively adopting the peripheral edge cut surface shape portions 11c and 12c and the arc-shaped portions 11e and 12e, it is possible to design and manufacture the press-fit terminal 1 according to the required performance. In addition, the maximum width W0 of the press-fit terminal 1 and the dimension of the inner diameter of the through hole 111 are set in a wide range, a design margin with respect to a performance standard (standard) is increased, an assembly defect rate is reduced, and a manufacturing cost is reduced. Furthermore, since products such as the press-fit terminal 1 and the semiconductor device 100 that satisfy various standards and have sufficient specifications can be shipped to customers, effects such as improvement in customer satisfaction, improvement in reliability, and reduction in customer claims can also be expected.

In the third aspect of the present embodiment, as illustrated in FIG. 10, the elastically deformed portion 10 is a pair of branch pieces (the first branch piece 11 and the second branch piece 12) that are bifurcated in the press-fitting direction D2, are separated from each other, and are curved such that the tips 11a and 12a thereof approach each other, and the first branch piece 11 and the second branch piece 12 have tip cut surface shape portions 11f and 12f (an example of a tip chamfered shape portion) at both ends in the deformation direction D1 of the elastically deformed portion 10 at the tips 11a and 12a. In addition, a semiconductor device 100 illustrated in FIG. 1 includes the press-fit terminal 1 according to the third aspect and a substrate 110 provided with a through hole 111 which is an example of an insertion hole. In addition, a semiconductor device 100 includes the press-fit terminal 1 according to the third aspect and a substrate 110 provided with a through hole 111 which is an example of an insertion hole.

As a result, even if eccentricity between the press-fit terminal 1 (the elastically deformed portion 10) and the through hole 111 occurs, the tips 11a and 12a of the first branch piece 11 and the second branch piece 12 are easily fitted in the opening portion of the through hole 111 when the elastically deformed portion 10 is press-fitted into the through hole 111. Therefore, the ability to assemble can be enhanced.

In addition, in the present embodiment, as illustrated in FIGS. 4C and 4F, the elastically deformed portion 10 is positioned at the peripheral edge of the cross section orthogonal to the press-fitting direction D2, and the four corner regions 10a in contact with the through hole 111 include one or more corner regions 10a which are the peripheral edge cut surface shape portions 11c and 12c and one or more corner regions 10a which are the peripheral edge round surface shape portions 11d and 12d.

By adopting the elastically deformed portion 10 having such a shape, it is possible to design and manufacture the press-fit terminal 1 further conforming to required performance.

In addition, in the present embodiment, as illustrated in FIG. 4F, two peripheral edge cut surface shape portions 11c and 12c are provided so as to face each other in one diagonal direction of the four corner regions 10a, and two peripheral edge round surface shape portions 11d and 12d are provided so as to face each other in the other diagonal direction of the four corner regions 10a.

As a result, as illustrated in FIG. 4C, as compared with an aspect in which the peripheral edge cut surface shape portions 11c and 12c are provided on the positive side in the Y direction of the elastically deformed portion 10 and the peripheral edge round surface shape portions 11d and 12d are provided on the negative side in the Y direction of the elastically deformed portion 10, it is possible to suppress variations in contact with the through hole 111 when the elastically deformed portion 10 is press-fitted.

Further, in the present embodiment, also in the first and second aspects described above, similarly to the third aspect described above, the elastically deformed portion 10 may be a pair of branch pieces bifurcated in the press-fitting direction D2 and separated from each other, and the tips 11a and 12a may be curved to approach each other.

Since the tips 11a and 12a of the first branch piece 11 and the second branch piece 12 are separated in this manner, the elastically deformed portion 10 is easily elastically deformed, and the maximum width W0 of the elastically deformed portion 10 is widened. Therefore, as described above, by providing the peripheral edge cut surface shape portions 11c and 12c and the arc-shaped portions 11e and 12e, it is possible to effectively prevent the plating of the elastically deformed portion 10 and the through hole 111 from being scraped, and the insertion load at the time of press-fitting and the extraction load at the time of extraction of the elastically deformed portion 10 from becoming too large.

In the third aspect of the present embodiment, as illustrated in FIG. 10, the tip chamfered shapes provided at both ends in the deformation direction D1 of the elastically deformed portion 10 in the tips 11a and 12a are the tip cut surface shape portions 11f and 12f provided in at least one of the four corner regions 10a.

As a result, the tips 11a and 12a of the first branch piece 11 and the second branch piece 12 can be easily fitted in the opening portion of the through hole 111 as compared with the aspect in which the tip chamfered shape is the tip round surface shape portion.

Hereinafter, the invention described in the claims of the originally filed application will be additionally described.

### Appendix 1

A press-fit terminal including:
an elastically deformed portion press-fitted into an insertion hole,
wherein the elastically deformed portion has four corner regions in contact with the insertion hole at a peripheral edge of a cross section orthogonal to a press-fitting direction, and at least one of the corner regions is a peripheral edge cut surface shape portion.

### Appendix 2

The press-fit terminal according to Appendix 1, wherein
the four corner regions include one or more of the corner regions that are the peripheral edge cut surface shape portions and one or more of the corner regions that are peripheral edge round surface shape portions.

### Appendix 3

The press-fit terminal according to Appendix 2, wherein
two peripheral edge cut surface shape portions are provided so as to face each other in one diagonal direction of the four corner regions, and
two peripheral edge round surface shape portions are provided so as to face each other in another diagonal direction of the four corner regions.

### Appendix 4

The press-fit terminal including:
an elastically deformed portion press-fitted into the insertion hole,
wherein the elastically deformed portion includes an arc-shaped portion having a center side of the insertion hole as a center of curvature at both ends in a deformation direction of the elastically deformed portion in the cross section orthogonal to the press-fitting direction.

### Appendix 5

The press-fit terminal according to any one of Appendixes 1 to 4, wherein
the elastically deformed portion is a pair of branch pieces that are bifurcated in the press-fitting direction, are separated from each other, and are curved such that tips thereof approach each other.

### Appendix 6

The press-fit terminal including:
an elastically deformed portion press-fitted into the insertion hole,
wherein the elastically deformed portion is a pair of branch pieces that are bifurcated in a press-fitting direction, are separated from each other, and are curved such that tips thereof approach each other, and
the pair of branch pieces have a tip chamfered shape portion at both ends in a deformation direction of the elastically deformed portion at the tips.

### Appendix 7

The press-fit terminal according to Appendix 6, wherein
the elastically deformed portion has four corner regions in contact with the insertion hole at a peripheral edge of a cross section orthogonal to the press-fitting direction, and
the tip chamfered shape portion is a tip cut surface shape portion provided in at least one of the four corner regions.

### Appendix 8

A semiconductor device including:
the press-fit terminal according to Appendixes 1, 4, and 6; and
a substrate provided with the insertion hole.

### Appendix 9

The press-fit terminal according to Appendix 1, wherein
the corner region is a region that connects a side in a deformation direction of the press-fit terminal and a side in a direction orthogonal to the deformation direction in a cross-sectional view orthogonal to the press-fitting direction.

As described above, the present invention has an effect of satisfying required performance or improving the ability to assemble, and for example, is useful for a semiconductor device such as a power semiconductor device.

What is claimed is:

1. A press-fit terminal configured to be press-fitted into an insertion hole, the press-fit terminal comprising:
a base portion; and
an insertion portion connected to the base portion and extending away from the base portion, the insertion portion being elastically deformable and configured to be press-fitted into the insertion hole in an insertion direction, wherein
the insertion portion has a cross section on a plane orthogonal to the insertion direction, the cross section having four corner portions positioned at four corners of a rectangle, respectively, and each being configured to be in contact with an inner surface of the insertion hole, and
the four corner portions of the cross section include at least one peripheral edge cut surface shape portion having a linear portion.

2. The press-fit terminal according to claim 1, wherein
the four corner regions further include at least one peripheral edge round surface shape portion having a rounded portion.

3. The press-fit terminal according to claim 2, wherein
the at least one peripheral edge cut surface shape portion comprises two peripheral edge cut surface shape portions, which are located at positions facing each other in one diagonal direction of the rectangle, and
the at least one peripheral edge round surface shape portions comprise two peripheral edge round surface shape portions, which are located at positions facing each other in another diagonal direction of the rectangle.

4. The press-fit terminal according to claim 1, wherein
the insertion portion is deformable in a direction of one side of the rectangle.

5. The press-fit terminal according to claim 1, wherein
the insertion portion is branched into a pair of branch pieces that are curved in opposite directions that are parallel to the plane so that tips of the pair of branch pieces approach each other.

6. A semiconductor device comprising:
the press-fit terminal according to claim 1; and
a substrate having the insertion hole.

7. A press-fit terminal, configured to be press-fitted into an insertion hole, the press-fit terminal comprising:
a base portion; and
an insertion portion connected to the base portion and extending away from the base portion, the insertion portion being elastically deformable and configured to be press-fitted into the insertion hole in an insertion direction, wherein
the insertion portion has a cross section on a plane orthogonal to the insertion direction, the cross section having two arc-shaped portions positioned facing each other, each arc of the arc-shaped portions being formed to correspond to a segment of a circumference of the insertion hole.

8. The press-fit terminal according to claim 7, wherein
the insertion portion is branched into a pair of branch pieces that are curved in opposite directions parallel to the plane so that tips of the pair of branch pieces approach each other.

9. A semiconductor device comprising:
the press-fit terminal according to claim 7; and
a substrate having the insertion hole.

10. A press-fit terminal, configured to be press-fitted into an insertion hole, the press-fit terminal comprising:
a base portion; and
an insertion portion connected to the base portion and extending away from the base portion, the insertion portion being elastically deformable and configured to be press-fitted into the insertion hole in an insertion direction, wherein
the insertion portion is branched into a pair of branch pieces that are curved in opposite directions orthogonal to the insertion direction so that tips of the pair of branch pieces approach each other, and
the tips of the pair of branch pieces respectively have a tip chamfered shape portion at ends thereof in the opposite directions.

11. The press-fit terminal according to claim 10, wherein
the insertion portion has a cross section on a plane parallel to the opposite directions, the cross section having four tip chamfered shape portions positioned at four corners of a rectangle on the plane and each being configured to be in contact with an inner surface of the insertion hole, and
the four tip chamfered shape portions include at least one tip cut surface shape portion having a liner portion.

12. A semiconductor device, comprising:
the press-fit terminal according to claim 11; and
a substrate having the insertion hole.
